(19) United States
(12) Patent Application Publication
(10) Pub. No.: US 2026/0096077 A1
(43) Pub. Date: Apr. 2, 2026

(54) WORK HEAD

(71) Applicant: FUJI CORPORATION, Chiryu (JP)

(72) Inventors: Kazuya MATSUYAMA, Chiryu-shi (JP); Masashi KIMURA, Nishio-shi (JP); Shingo AOKI, Tougou-cho (JP); Masanari MATSUMOTO, Chiryu-shi (JP)

(73) Assignee: FUJI CORPORATION, Chiryu (JP)

(21) Appl. No.: 19/112,708

(22) PCT Filed: Nov. 15, 2022
(86) PCT No.: PCT/JP2022/042365

§ 371 Date: Mar. 18, 2025

(51) Int. Cl. H05K 13/08

(52) U.S. Cl. CPC H05K 13/0812

(57) ABSTRACT

A work head for performing work on a board in a board work machine includes: an LED package configured to be used by an imaging device, in which the LED package is turned on selectively in a first mode in which the LED package is turned on when imaging is performed by the imaging device and a second mode in which the LED package is turned on when imaging is not performed by the imaging device.

### TECHNICAL FIELD

The present disclosure relates to a work head for performing work on a board in a board work machine.

### BACKGROUND ART

The following Patent Literature describes that, when luminance of an LED package is reduced by a gas entering sealing resin of the LED package, the LED package is turned on under a predetermined environment to recover the luminance of the LED package.

### CITATION LIST

### Patent Literature

Patent Literature 1: JP-A-2017-117993

### BRIEF SUMMARY

### Technical Problem

An object of the present description is to recover luminance of an LED package in a work head including the LED package.

### Solution to Problem

In order to solve the above problem, the present description discloses a work head for performing work on a board in a board work machine, the work head including: an LED package configured to be used by an imaging device, in which the LED package is turned on selectively in a first mode in which the LED package is turned on when imaging is performed by the imaging device and a second mode in which the LED package is turned on when imaging is not performed by the imaging device.

### Advantageous Effects

In the present disclosure, a work head includes an LED package configured to be used by an imaging device, in which the LED package is turned on selectively in a first mode in which the LED package is turned on when imaging is performed by the imaging device and a second mode in which the LED package is turned on when imaging is not performed by the imaging device. Accordingly, it is possible to perform imaging by turning on the LED package in the first mode, and to recover luminance of the LED package by turning on the LED package in the second mode.

### BRIEF DESCRIPTION OF DRAWINGS

FIG. 1 is a perspective view showing a board work system.

FIG. 2 is a perspective view showing a mounting device.

FIG. 3 is a schematic view showing a mounting head.

FIG. 4 is a perspective view showing an LED package.

FIG. 5 is a block diagram showing a control device.

FIG. 6 is a schematic view showing a mounting head of a second example.

### DESCRIPTION OF EMBODIMENTS

Hereinafter, as exemplary embodiments of the present disclosure, examples of the present disclosure will be described in detail with reference to drawings.

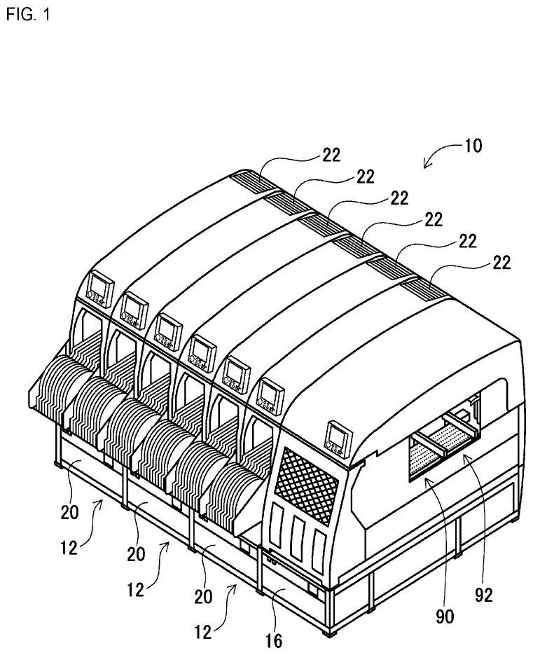

FIG. 1 shows board work system 10. Board work system 10 shown in FIG. 1 is a system for producing a circuit board on which electronic components are mounted. Board work system 10 includes three electric component mounting devices (hereinafter, may be abbreviated as “mounting devices”) 12 disposed adjacent to each other, and reflow oven 16.

Mounting device 12 includes one system base 20 and two electronic component mounters (hereinafter, may be abbreviated as “mounters”) 22 disposed adjacent to each other on system base 20. That is, six mounters 22 are arranged in a row. When six mounters 22 are distinguished from each other, mounters 22 may be referred to as first to sixth mounters 22 from mounter 22 disposed most upstream to mounter 22 disposed most downstream.

Reflow oven 16 is disposed downstream of mounter 22 which is disposed most downstream among six mounters 22, that is, sixth mounter 22. In the following description, a direction in which mounter 22 and reflow oven 16 are arranged is referred to as an X-axis direction, and a horizontal direction perpendicular to the X-axis direction is referred to as a Y-axis direction.

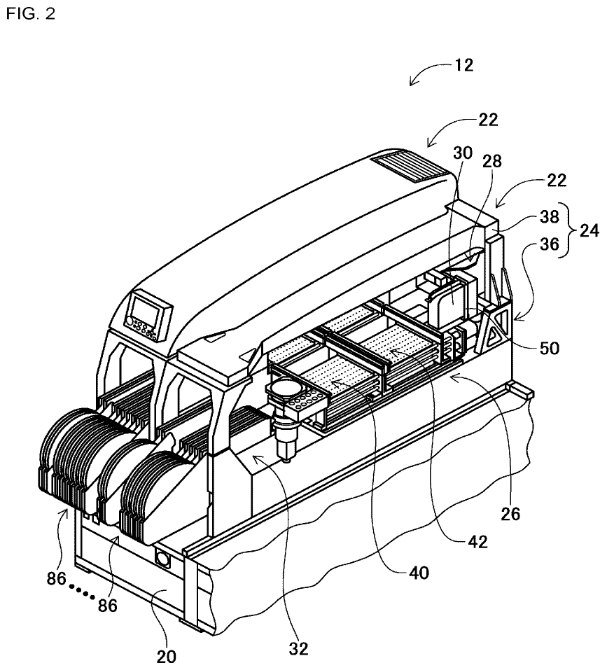

First, mounting devices 12 will be described. Since three mounting devices 12 have substantially the same configuration, one mounting device 12 of three mounting devices 12 will be described as a representative. As shown in FIG. 2, mounting device 12 includes one system base 20 and two mounters 22 adjacent to each other on system base 20. Each mounter 22 mainly includes mounter main body 24, conveyance device 26, mounting head moving device (hereinafter, may be abbreviated as “moving device”) 28, mounting head 30, and supply device 32.

Mounter main body 24 includes frame 36 and beam 38 mounted on frame 36.

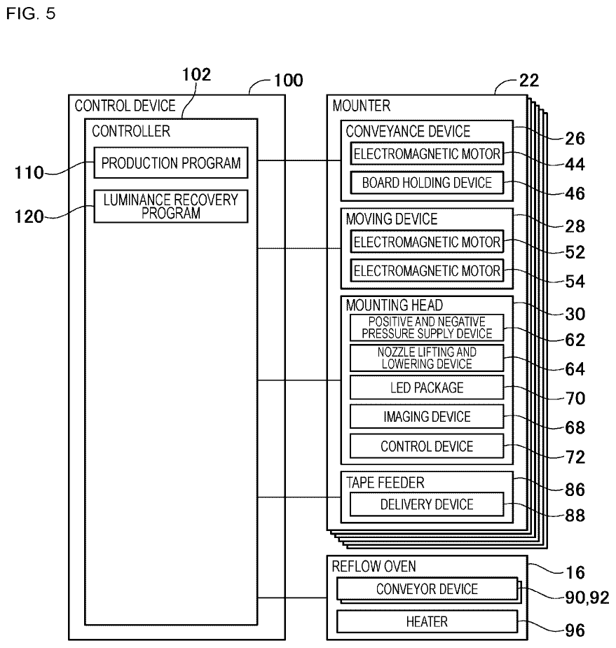

Conveyance device 26 includes two conveyor devices 40 and 42. Two conveyor devices 40 and 42 are disposed on frame 36 to be parallel to each other and to extend in the X-axis direction. Each of two conveyor devices 40 and 42 conveys a circuit board supported on each of conveyor devices 40 and 42 in the X-axis direction with electromagnetic motor (refer to FIG. 5) 44. The circuit board conveyed by each of conveyor devices 40 and 42 is held by board holding device (refer to FIG. 5) 46 at predetermined positions.

Moving device 28 is an XY robot type moving device. Moving device 28 includes electromagnetic motor (refer to FIG. 5) 52 that slides slider 50 in the X-axis direction and electromagnetic motor (refer to FIG. 5) 54 that slides slider 50 in the Y-axis direction. Mounting head 30 is attached to slider 50, and mounting head 30 moves to any position on frame 36 by operations of two electromagnetic motors 52 and 54. Mounting head 30 is attached to and detached from slider 50 by one touch without using a tool or the like by a worker.

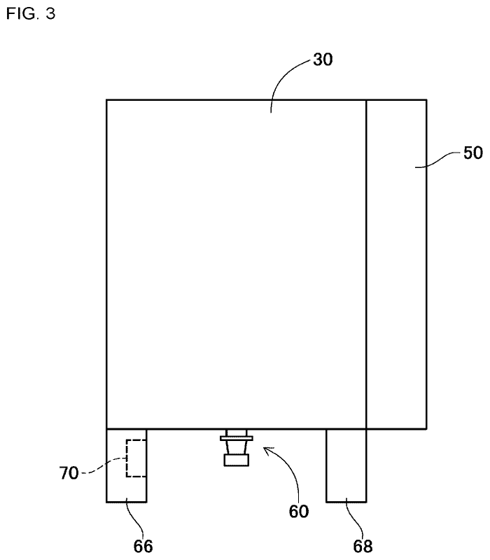

Mounting head 30 mounts an electronic component on a circuit board. As shown in FIG. 3, mounting head 30 includes suction nozzle 60 provided at a center of a lower end surface. Suction nozzle 60 communicates with positive and negative pressure supply device (refer to FIG. 5) 62 via negative pressure air and positive pressure air passages. Suction nozzle 60 picks up and holds an electronic component by using a negative pressure, and separates the held electronic component by using a positive pressure. In addition, mounting head 30 includes nozzle lifting and lowering device (refer to FIG. 5) 64 that lifts and lowers suction nozzle 60. Mounting head 30 changes a position of the held electronic component in an up-down direction with nozzle lifting and lowering device 64. Further, mounting head 30 includes lighting device 66 and imaging device 68 disposed to interpose suction nozzle 60 therebetween on the lower end surface. LED package 70 is incorporated in lighting device 66, and lighting device 66 is disposed on the lower end surface of mounting head 30 in a posture in which LED package 70 faces a tip of suction nozzle 60. Imaging device 68 is disposed at a position in which imaging device 68 faces lighting device 66 with suction nozzle 60 as a center. Accordingly, the electronic component held by suction nozzle 60 is imaged by imaging device 68 in a state of being lit by LED package 70 of lighting device 66. Mounting head 30 includes control device (refer to FIG. 5) 72, and operations of nozzle lifting and lowering device 64, lighting device 66, and imaging device 68 are controlled by control device 72.

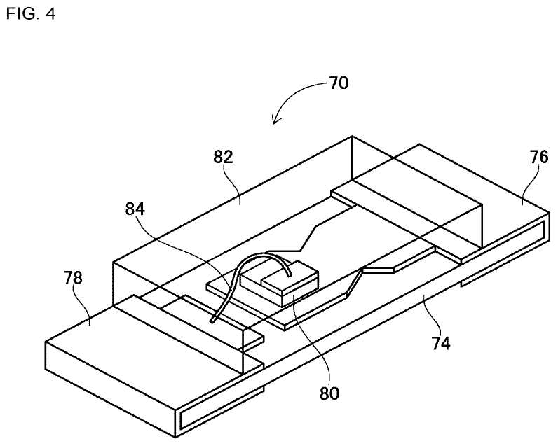

As shown in FIG. 4, LED package 70 includes package board 74, a pair of lead frames 76 and 78, LED element 80, and sealing resin 82. Package board 74 has a generally longitudinal shape, and the pair of lead frames 76 and 78 are disposed at both end portions of package board 74 in a longitudinal direction. LED element 80 is fixed to first lead frame 76 of the pair of lead frames 76 and 78, and second lead frame 78 and LED element 80 are connected via wire 84. LED element 80 that is fixed to lead frame 76 and wire 84 that connects lead frame 78 and LED element 80 are covered by sealing resin 82.

As shown in FIG. 2, supply device 32 is a feeder type supply device and is disposed at an end portion of frame 36. Supply device 32 includes multiple tape feeders 86. Tape feeder 86 accommodates a taped component that are wound therearound. The taped component is obtained by taping electronic components on a carrier tape. Tape feeder 86 feeds the taped component with feeding device (refer to FIG. 5) 88. Consequently, feeder type supply device 32 supplies an electronic component at a supply position by feeding the taped component.

Reflow oven 16 is a device that heats a circuit board on which an electronic component is mounted to melt cream solder and then fixes the electronic component onto the circuit board. Reflow oven 16 is connected to mounter 22 disposed most downstream among six mounters 22, that is, sixth mounter 22. Reflow oven 16 includes conveyor devices 90 and 92 having the same structure as conveyor devices 40 and 42 of mounter 22. Conveyor device 90 of reflow oven 16 is connected to conveyor device 40 of sixth mounter 22, and conveyor device 92 of reflow oven 16 is connected to conveyor device 42 of sixth mounter 22. Reflow oven 16 includes heater (refer to FIG. 5) 96 that heats a circuit board conveyed by each of conveyor devices 90 and 92.

In addition, as shown in FIG. 5, board work system 10 includes control device 100. Control device 100 includes controller 102, and controller 102 is connected to conveyance device 26, moving device 28, and mounting head 30 of mounter 22, tape feeder 86, and reflow oven 16. Controller 102 includes CPU, ROM, RAM, and the like, and is mainly configured with a computer. Accordingly, operations of conveyance device 26, moving device 28, and mounting head 30 of mounter 22, tape feeder 86, and reflow oven 16 are controlled by controller 102. Controller 102 stores production program 110, and controller 102 produces a circuit board by controlling the operations of mounters 22 and reflow oven 16 in accordance with production program 110.

Specifically, first, when a circuit board is carried into first mounter 22, controller 102 outputs a command in accordance with production program 110, so that conveyance device 26 of first mounter 22 conveys the circuit board to a work position and fixedly holds the circuit board at the position. In addition, tape feeder 86 feeds a taped component and supplies an electronic component at the supply position in response to the command of controller 102 according to production program 110. Then, mounting head 30 moves above the supply position of the electronic component in response to the command of controller 102 according to production program 110, and the electronic component is picked up and held by suction nozzle 60. Subsequently, mounting head 30 turns on LED package 70 in response to the command of controller 102 according to production program 110, and the electronic component held by suction nozzle 60 is imaged. Then, controller 102 calculates a holding position, a holding posture, and the like of the electronic component based on imaging data. Next, mounting head 30 moves above the circuit board in response to the command of controller 102 according to production program 110, and mounts the held electronic component on the circuit board. In this case, an orientation, a posture, and the like of the electronic component held by suction nozzle 60 are corrected based on the calculated holding position, holding posture, and the like of the electronic component, and the electronic component is mounted on the circuit board. Then, when mounting work of the electronic component on the circuit board in first mounter 22 is ended, conveyance device 26 conveys the circuit board toward a downstream side in response to the command of controller 102 according to production program 110. Accordingly, the circuit board is carried into second mounter 22.

Hereinafter, in the second mounter to the sixth mounter, the same work as in the first mounter described above is subsequently performed, so that the mounting work of the electronic component on the circuit board is completed. When the circuit board on which the mounting work has been completed is carried into reflow oven 16, conveyor devices 90 and 92 of reflow oven 16 convey the circuit board to the work position and fixedly hold the circuit board at the work position in response to the command of controller 102 according to production program 110. Subsequently, heater 96 heats the circuit board to melt the cream solder in response to the command of controller 102 according to production program 110, so that the electronic component is fixed onto the circuit board. Then, conveyor devices 90 and 92 convey the circuit board toward the downstream side in response to the command of controller 102 according to production program 110. Accordingly, the circuit board is carried out of reflow oven 16, and the circuit board is produced.

As described above, in board work system 10, the mounting work of the electronic component is performed in mounters 22 and the cream solder is heated in reflow oven 16, whereby the circuit board is produced. Meanwhile, when the cream solder is heated in reflow oven 16, VOC (abbreviation of Volatile Organic Compounds) is generated, and luminance of LED package 70 of mounting head 30 in mounter 22 may decrease due to the VOC. Specifically, since silicone resin or the like is used as sealing resin 82 of LED package 70 and the silicone resin is likely to cause a gas to pass therethrough, the VOC enters sealing resin 82 of LED package 70. When LED package 70 is turned on in a state in which the VOC has entered sealing resin 82, the VOC changes inside sealing resin 82 and a color thereof changes. Therefore, a transmittance of sealing resin 82 decreases, and the luminance of LED package 70 decreases.

In view of this, controller 102 of control device 100 stores luminance recovery program 120, and controller 102 recovers the luminance of LED package 70 in accordance with luminance recovery program 120. Specifically, in sealing resin 82 whose color has been changed by the VOC, LED package 70 is turned on in an environment in which the VOC is small, so that a component that has caused the color change of sealing resin 82 is released from sealing resin 82, and the luminance of LED package 70 is recovered. During the mounting work in board work system 10, it is considered that reflow oven 16 is in operation and a concentration of the VOC in the board work system 10 is high. Therefore, when the mounting work is not performed in board work system 10, that is, when the work on a circuit board is not executed, luminance recovery work of LED package 70 is executed in accordance with luminance recovery program 120.

Specifically, luminance recovery program 120 outputs a turn-on command of LED package 70 to mounting head 30 when the work is not executed on the circuit board. Among six mounters 22, the fifth mounter and the sixth mounter disposed at positions close to reflow oven 16 have a high concentration of the VOC, and the luminance of LED package 70 is significantly reduced, so that luminance recovery program 120 outputs the turn-on command to mounting heads 30 of the fifth mounter and the sixth mounter. Then, in mounting head 30 that has received the turn-on command, control device 72 of mounting head 30 turns on LED package 70 by controlling the operation of LED package 70. As described above, when the work is not executed on the circuit board, LED package 70 of mounting head 30 is turned on in the fifth mounter and the sixth mounter adjacent to reflow oven 16, and thus it is possible to recover the decreased luminance of LED package 70 due to the VOC generated from reflow oven 16.

It goes without saying that suction nozzle 60 naturally does not hold the electronic component when LED package 70 is turned on when the work is not executed on the circuit board. Therefore, even when LED package 70 is turned on when the work is not executed on the circuit board, imaging using imaging device 68 is not performed. That is, when LED package 70 is turned on for the purpose of recovering the luminance of LED package 70, LED package 70 is turned on in a mode in which LED package 70 is turned on when imaging is not performed by imaging device 68. To the contrary, when LED package 70 is turned on in a case where the work is executed on the circuit board, suction nozzle 60 holds the electronic component, and imaging using imaging device 68 is performed. That is, when LED package 70 is turned on for the purpose of imaging the electronic component, LED package 70 is turned on in a mode in which LED package 70 is turned on when imaging is performed by imaging device 68. Therefore, LED package 70 is turned on selectively in a first mode in which LED package 70 is turned on when imaging is performed and a second mode in which LED package 70 is turned on when imaging is not performed. In other words, LED package 70 is turned on selectively in the first mode in which LED package 70 is turned on when the component is held by suction nozzle 60 and the second mode in which LED package 70 is turned on when the electronic component is not held by suction nozzle 60. In other words, LED package 70 is turned on selectively in the first mode in which LED package 70 is turned on for the purpose of imaging the electronic component and the second mode in which LED package 70 is turned on for the purpose of recovering the luminance of LED package 70. As described above, by turning on LED package 70 selectively in the first mode and the second mode, it is possible to recover the luminance of LED package 70 for imaging.

The turning-on of LED package 70 may be continuous turning-on or intermittent turning-on. Incidentally, the intermittent turning-on is so-called blinking in which turning-on and turning-off are repeated. By intermittently turning on LED package 70, damage to LED package 70 due to a high temperature can be reduced. In addition, a timing at which the turn-on command of LED package 70 is output when the work is not executed on the circuit board is a timing at which the circuit board as a production target is changed, for example, a timing at which a factory or the like in which board work system 10 is installed is not in operation during setup change work, for example, night. The turn-on command may be output at a predetermined cycle, for example, every day, or may be output when a decrease in the luminance of LED package 70 is confirmed. As a method of confirming the decrease in the luminance of LED package 70, LED package 70 is turned on when the work is not executed on the circuit board, and imaging using imaging device 68 is performed. In this case, since the electronic component is not held by suction nozzle 60, light emitted by LED package 70 is imaged by imaging device 68. Next, brightness, saturation, and the like are calculated based on the imaging data obtained by the imaging, and the luminance of LED package 70 is estimated. Then, when the estimated luminance is equal to or lower than a threshold, it is recognized that the luminance of LED package 70 is reduced, and the turn-on command of LED package 70 is output. When the luminance recovery work of LED package 70 is executed after the luminance of LED package 70 decreases to the threshold or lower, a time required for the luminance recovery work may be considerably long. Therefore, by outputting the turn-on command at the predetermined cycle, it is possible to prevent the luminance of LED package 70 from decreasing.

Luminance recovery program 120 can also output the turn-on command of LED package 70 at a time reserved in advance. That is, the worker sets, in luminance recovery program 120, a time during which the work is assumed not to be executed on the circuit board. Then, luminance recovery program 120 outputs the turn-on command of LED package 70 at the set time. Accordingly, it is possible to perform the luminance recovery work of LED package 70 at the time desired by the worker.

Cream solder and silver paste used for the production of the circuit board are also exemplified as a cause of VOC generation. That is, a solvent contained in the cream solder, the silver paste, or the like volatilizes to become VOC. Therefore, when cream solder, silver paste, or the like is used in a large amount in the circuit board as the production target, the turn-on command of LED package 70 is not output only to the fifth mounter and the sixth mounter as described above, but is output to all of the first to sixth mounters.

Specifically, luminance recovery program 120 specifies a type of the circuit board as the production target based on production program 110. The circuit board as the production target is a circuit board produced by board work system 10 when LED package 70 is turned on in a mode in which LED package 70 is turned on when imaging is performed by imaging device 68, that is, in the first mode. Since production program 110 is a program for producing a circuit board as described above, luminance recovery program 120 can specify the type of the circuit board as the production target based on production program 110. Then, luminance recovery program 120 determines whether cream solder, silver paste, or the like is used in a large amount in the specified type of the circuit board. In this case, for example, information indicating the type of the circuit board in which cream solder, silver paste, or the like is used in a large amount may be programmed in luminance recovery program 120, and luminance recovery program 120 may determine whether the type of the circuit board as the production target is the circuit board in which cream solder, silver paste, or the like is used in a large amount based on the information. In addition, when a usage amount of cream solder, silver paste, or the like used in the circuit board specified based on production program 110 can be estimated, when the estimated usage amount is equal to or greater than a threshold, it may be determined that the type of the circuit board as the production target is a circuit board in which cream solder, silver paste, or the like is used in a large amount. Then, when it is determined that the type of the circuit board as the production target is a circuit board in which cream solder, silver paste, or the like is used in a large amount, luminance recovery program 120 outputs the turn-on command of LED package 70 to all of the first to sixth mounters. Accordingly, by performing the luminance recovery work after the work is executed on the circuit board in which the cream solder, the silver paste, or the like is used in a large amount, it is possible to recover the decreased luminance of LED package 70 due to the VOC generated from the cream solder, the silver paste, or the like. In particular, since lighting device 66 including LED package 70 is disposed on the lower end surface of mounting head 30, and LED package 70 approaches a position close to an upper surface of the circuit board during the mounting work, the influence of VOC generated from cream solder, silver paste, or the like on LED package 70 is large. In consideration of this, it is possible to recover the decreased luminance of LED package 70 at a suitable timing by performing the luminance recovery work after the work is executed on the circuit board in which cream solder, silver paste, or the like is used in a large amount.

The luminance recovery work is started based on the turn-on command of LED package 70, but is ended when the luminance of LED package 70 is recovered. Specifically, LED package 70 is turned on in a state in which suction nozzle 60 does not hold the electronic component, and in this case, the light of LED package 70 is imaged by imaging device 68, so that it is possible to estimate the luminance of LED package 70 based on the imaging data. Therefore, when the luminance recovery work is executed, imaging using imaging device 68 is performed at a predetermined cycle. It is noted that the imaging using imaging device 68 when the luminance recovery work is executed is intended to estimate the luminance, and is not intended to image the electronic component. Then, the luminance is estimated based on the imaging data each time imaging using imaging device 68 is performed, and it is determined whether the estimated luminance exceeds the threshold. In this case, if it is determined that the estimated luminance exceeds the threshold, the luminance recovery work is ended. The luminance recovery work may be ended after the luminance recovery work is continuously executed for a predetermined time regardless of whether the luminance of LED package 70 is recovered.

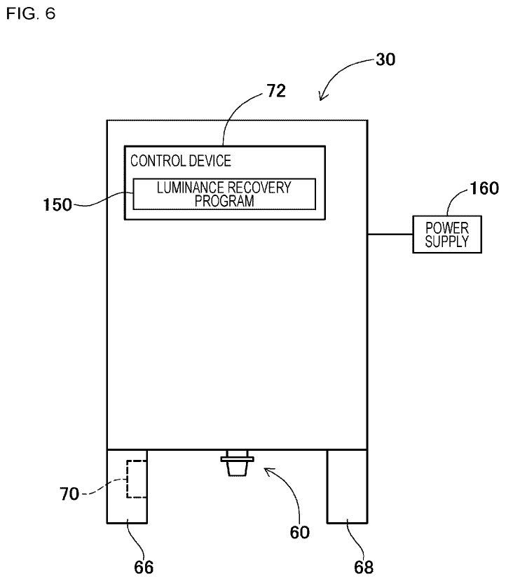

In a first example described above, the luminance recovery work is executed when mounting head 30 is mounted inside mounter 22, but in a second example, the luminance recovery work is executed when mounting head 30 is taken out of mounter 22. Specifically, as described above, mounting head 30 is attachable to and detachable from slider 50 of moving device 28. Therefore, mounting head 30 can be removed from slider 50 and taken out of mounter 22. In addition, the concentration of the VOC is usually low outside mounter 22 except near board work system 10. Therefore, the luminance recovery work is executed when mounting head 30 is taken out of mounter 22. In mounting head 30 in which the luminance recovery work is executed when mounting head 30 is taken out of mounter 22, as shown in FIG. 6, luminance recovery program 150 is stored in control device 72 of mounting head 30. Since a battery is not incorporated in mounting head 30, mounting head 30 taken out of mounter 22 is connected to power supply 160.

In this manner, the luminance recovery work is executed in accordance with luminance recovery program 150 in a state in which mounting head 30 is taken out of mounter 22 and connected to power supply 160. That is, when luminance recovery program 150 detects removal of mounting head 30 from slider 50 and power is supplied to mounting head 30 by connection of mounting head 30 to power supply 160, luminance recovery program 150 outputs the turn-on command to LED package 70. It goes without saying that suction nozzle 60 does not hold a component outside mounter 22, and imaging device 68 does not image the component when LED package 70 is turned on. Therefore, LED package 70 is turned on in the second mode, and imaging device 68 does not perform imaging. As described above, in a state in which mounting head 30 is taken out of mounter 22, LED package 70 is turned on in the second mode, so that it is possible to suitably recover the luminance of LED package 70. Further, since the luminance recovery work is executed outside mounter 22, it is possible to recover the luminance of LED package 70 without stopping the mounting work or the like in board work system 10.

Mounter 22 is an example of a board work machine. Mounting head 30 is an example of a work head. Imaging device 68 is an example of an imaging device. LED package 70 is an example of an LED package. Production program 110 is an example of a program.

The present disclosure is not limited to the above-described examples, and can be implemented in various forms with various changes and improvements based on the knowledge of those skilled in the art. Specifically, for example, in the above-described example, the luminance recovery work is executed in accordance with luminance recovery programs 120 and 150, but the luminance recovery work may be executed by a user operation. For example, operation buttons may be disposed on an operation panel of mounter 22, mounting head 30, control device 100, and the like, and the luminance recovery work may be executed by operating the operation buttons. Further, the present disclosure is not limited to the operation buttons, and the luminance recovery work may be executed by the worker inputting the turn-on command of the LED package. When the operation of the operation buttons or the input of the turn-on command by the worker is performed when the work on the circuit board is executed, it is desirable that the operation, the input, and the like are canceled and the luminance recovery work is not executed.

In the above-described example, LED package 70 emits light toward the tip of suction nozzle 60 as an imaging target, but the imaging target is not limited to the electronic component held by suction nozzle 60, and various objects can be imaged. For example, when the circuit board is the imaging target, LED package 70 emits light toward the circuit board.

Although the present disclosure is applied to mounting head 30 in the above-described example, the present disclosure may be applied to various work heads such as an inspection head and a discharge head.

In the first example described above, luminance recovery program 120 specifies the type of the circuit board as the production target based on production program 110, but the type of the circuit board as the production target may be acquired from a host computer, a cloud, or the like.

In the first example described above, the luminance recovery work is executed when the type of the circuit board as the production target is the circuit board in which cream solder, silver paste, or the like is used in a large amount, but the luminance recovery work may be executed when the type of the circuit board as the production target is another specific type of the circuit board. Examples of the other specific type of the circuit board include a circuit board on which a treatment using a material containing VOC is executed.

In addition, in the first example described above, the luminance recovery work is executed in mounter 22 installed near reflow oven 16, but the luminance recovery work may be executed in mounter 22 installed near a work machine other than reflow oven 16, for example, a solder printer.

In the first example described above, luminance recovery program 120 is stored in control device 100, but luminance recovery program 120 may be stored in mounting head 30.

In the second example described above, mounting head 30 removed from mounter 22 is connected to power supply 160 and the luminance recovery work is executed, but mounting head 30 may be connected to a maintenance unit, a cleaner unit, or the like and the luminance recovery work may be executed. Accordingly, it is possible to perform the luminance recovery work together with maintenance or cleaning of mounting head 30. When mounting head 30 is connected to the maintenance unit, the cleaner unit, or the like and the luminance recovery work is executed, luminance recovery program 150 may be stored in the maintenance unit or the like instead of mounting head 30.

### REFERENCE SIGNS LIST

22: mounter (board work machine), 30: mounting head (work head), 68: imaging device, 70: LED package, 110: production program (program)

1. A work head for performing work on a board in a board work machine, the work head comprising:
an LED package configured to be used by an imaging device,
wherein the LED package is turned on selectively in a first mode in which the LED package is turned on when imaging is performed by the imaging device and a second mode in which the LED package is turned on when imaging is not performed by the imaging device.

2. The work head according to claim 1, wherein the LED package is turned on in the first mode when the work head executes work on a board, and the LED package is turned on in the second mode when the work head does not execute work on a board.

3. The work head according to claim 2, wherein the LED package is turned on in the second mode according to a type of work executed when the LED package is turned on in the first mode when the work head does not execute work on a board.

4. The work head according to claim 3, wherein the type of the work is specified based on a program for executing work on a board on the board work machine, and the LED package is turned on in the second mode according to the specified type of the work.

5. The work head according to claim 2, wherein the LED package is turned on in the second mode at a time reserved in advance when the work head does not execute work on a board.

6. The work head according to claim 1, wherein the LED package is turned on in the first mode when the work head is mounted inside the board work machine, and the LED package is turned on in the second mode when the work head is removed from the board work machine.
